(19) United States
(12) Patent Application Publication
(10) Pub. No.: US 2005/0241691 A1
(43) Pub. Date: Nov. 3, 2005

(54) Space Construction

(76) Inventor: Glenn Mark Wakefield, Tempe, AZ (US)

Correspondence Address: Glenn Wakefield, 1416 East Carmen Street, Tempe, AZ, 85283, US

(21) Appl. No.: 11/011,460

(22) Filed: Dec. 14, 2004

Related U.S. Application Data
(60) Provisional application No. 60/535,280, filed on Jan. 10, 2004.

(51) Int. Cl. H01L 31/00

(52) U.S. Cl. 136/251; 136/252; 136/244

(57) ABSTRACT

Space construction (surface based and outer space) may require specially designed construction material and power sources to establish a time efficient, cost effective structure. On the threaded end of a bolt may be added an unthreaded cylindrical section followed by a tapered section. Construction material may be modified with male/female parts to permit the alignment of materials relative to one another and to align bolt holes. A cost effective power system may be established by the appropriate backplane thinning of solar cells and subsequent attachment to a thin sheet providing a minimal weight power source.

### CROSS-REFERENCE TO RELATED APPLICATIONS

Provisional application No. 60/526,000, filed December 2003.

Provisional application No. 60/535,280, filed January 2004.

### STATEMENT REGARDING FEDERALLY SPONSORED RESEARCH OR DEVELOPMENT

Not Applicable

### REFERENCE TO SEQUENCE LISTING, A TABLE, OR A COMPUTER PROGRAM LISTING COMPACT PACT DISC APPENDIX

Not Applicable

### BACKGROUND OF THE INVENTION

This patent applies to the field of space construction (surface based and outer space).

Space construction may make use of robotic technology to aid construction. An outer space base of substantial size and capability may require a linear magnetic launcher (or a new propulsion technology) to move the necessary material from the surface (i.e. moon/planet/asteroid) to the outer space location. Surface base construction may make effective use of the local resources. A power system may be based on solar panels located in space with the collected energy beamed to earth by electromagnetics.

### BRIEF SUMMARY OF THE INVENTION

Space construction (surface based and outer space) may require specially designed construction material and power sources to establish a time efficient, cost effective structure. On the threaded end of a bolt may be added an unthreaded cylindrical section followed by a tapered section. Construction material may be modified with male/female parts to permit the alignment of materials relative to one another and to align bolt holes. A cost effective power system may be established by the appropriate backplane thinning of solar cells and subsequent attachment to a thin sheet providing a minimal weight power source.

### BRIEF DESCRIPTION OF THE SEVERAL VIEWS OF THE DRAWING

Not Applicable

### DETAILED DESCRIPTION OF THE INVENTION

Building structures in space may be categorized as surface based construction (moon/planet/asteroid) and space based construction (outer space). Surface based construction may have minimal or excessive gravity, may have a toxic atmosphere or may not have an atmosphere, may have widely varying or extreme temperature conditions and may have high radiation exposure. Space based construction will have almost no gravity, will be almost a vacuum, will be several Kelvin in the shade and may have high radiation exposure. These highly varied conditions require special consideration in any space endeavor. The building of a structure will involve the joining together of components. All construction material may have appropriate male/female interfaces. These interfaces may serve to align parts (i.e. alignment of attachment sites (bolt holes) by aligning the male/female interface, the correct placement of a piece of material relative to other pieces of material by aligning the male/female interface). The construction material may be designed so that additions may be continuously added to an existing structure. All the construction/power material may be prefabricated and sent to the desired destination for efficient human/robotic construction. Take for instance two tubes which may be attached end to end by bolting their two faceplates together. The end plates may be aligned by an appropriate male/female interface (i.e. slightly raised structures that are associated with each bolt hole on one face plate will have a corresponding mating pattern on the matching face plate). This special structure allows for easy robotic alignment. Next a special bolt will be inserted through a face plate hole. The bolt will be similar to available bolts except at the threaded end. Here there will be an extension consisting of an unthreaded cylindrical section followed by an unthreaded tapered or conical section. The length of the cylindrical section may be appropriately chosen (i.e. the width of a nut). The diameter of the cylindrical section will be slightly less than the inside diameter of the nut. The diameter of the cylindrical and tapered/conical sections are equal at their junction. The junctional end of the conical section has the largest conical diameter. The edges are appropriately contoured. Any quantity of material may be removed from the cylindrical and tapered/conical sections such that the remaining material is sufficient to guide the nut. All dimensions are appropriate for the particular application. This special bolt will allow the robot/human to easily complete the following series of maneuvers. Place the bolt through the bolt hole, place the nut on the bolts align/start the nut on the threads and tighten the nut appropriately. The tubes may be connected (bolted) at right angles or any necessary orientation. The mating surfaces surrounding the bolt holes and the special bolts will be used in all viable situations for efficiency. A solar power supply with the ability to run the surface/space base at full capacity is vital to mission success. A large surface area is required to produce the necessary energy; hence, minimal space and weight are a requirement. Assuming an area of 1 m on a side produces 1 kw than an area 100 m on a side with a 10% solar cell efficiency would yield 1000 kw. Three main types of solar cells are available: monocrystalline, polycrystalline and amorphous. The electrical characteristics of monocrystalline and polycrystalline solar cells are stable over the long term; but, both types are very heavy. The electrical characteristics of amorphous solar cells degrade quickly; but, these cells can be manufactured as a light flexible sheet providing for minimal weight. All three types of solar cells have major drawbacks for space application. This situation can be remedied by taking monocrystalline, polycrystalline and other types of solar cells and thinning the backplane to an appropriate thickness (i.e. less than 1 mm). Place an appropriate electrical pattern on the thinned solar cell. A thin flexible sheet with the appropriate electrical patterns may be attached to the solar cell through surface preparation, heat, pressure and chemicals. An appropriate connection is established between the flexible sheet and the end user (i.e. power conversion, beam energy from solar cells to surface via electromagnetics). Very large sheets of solar cells may be manufactured, folded and placed inside the launch vehicle. Once the destination is reached the sheet will be spread out providing a large, stable, long term power supply.

1.) Surface Base

A unmanned surface base may be established quickly, may provide for the testing of basic engineering principles, may obviate the need for life-support/protection considerations and may be low cost. This eventually will be transformed into a manned surface base. The basic components needed in establishing a surface base include a solar power source and robotic equipment able to process a variety of surface elements/compounds. The electrically powered robotic equipment will involve the breaking up and shoveling of surface material into an initial processing chamber, melting and further processing of the material, pouring the molten liquid into molds (i.e. tubes, beams, bars, plates, sheets, bolts, nuts, . . . ), fabricating the necessary parts and building the surface base. As heavy rocket boosters may lift a large payload, these specially designed robots will be of a substantial size and weight (i.e. small size earth moving equipment—bulldozer, drilling rig). The specially designed fabrication equipment will entail a complete machine shop (i.e. laser/bit CNC mill, laser/tool bit CNC lathe, bit fabricating machine, . . . ). The laser CNC mill will have the ability to build a specially designed component layer by layer. New molds may be produced on the moon. The surface base, which may take any form, may be made air tight through the laser sealing of components. Derived from local materials (i.e. metals, glass, . . . ), the basic structure, plumbing system, electrical system, furniture, bathroom, kitchen, rooms, working area, doors and shelving will all be fabricated and pieced together. The robots assigned to the actual construction may move about on wheels with energy supplied through a power cord/transmitted electromagnetic radiation/rechargeable power pack. The entire system may be reprogrammed while on the surface to allow for new capabilities or corrections. The main power source may provide a temperate environment within the enclosable landing module and eventually within the surface structure. Excess power generated may be stored in batteries, hydrogen/oxygen, ultracapacitors or flywheels. All of these energy storage systems need to be evaluated based on their energy capacity, weight and long term viability. The hydrogen and oxygen may be stored in lightweight carbon fiber tanks and released to the fuel cell on demand to produce electricity and water. When excessive power is generated it may be used to split water into hydrogen and oxygen. This will be a closed system recycling the hydrogen, oxygen and water. The hydrogen and oxygen (hydrocarbons may be processed if available) may also serve to refuel a rocket to leave the surface. If power is sufficient, work may be carried out around the clock by appropriately allocating the various tasks. The module may be landed on the surface under rocket propulsion to provide for a soft touchdown. The selection of the landing site is important for mission success. The size of the surface base may be continuously enlarged and prepared for human habitation. The next step in preparation for human habitation will be to establish an air tight enclosed atmosphere within the space base compatible with plant and animal life—carbon dioxide, oxygen, nitrogen, water vapor. These atmospheric elements/compounds may be extracted from the local soil or atmosphere (if it exists). Even if they are present in very small quantities, a sufficient amount of soil will be processed to obtain the correct atmospheric components. An area of the surface base will be set aside for the establishment of a plant biome. The soil for the plant biome will be composed of processed and sterilized local soil so that the basic constituents necessary for plant growth are present. Although very few compounds are required for successful plant growth (as demonstrated by hydroponics), many trace minerals are crucial for long term human health. It will be necessary that eventual human inhabitants bring along a multivitamin and mineral supplement to provide for their daily needs. Once a selected set of seeds are planted and a stable environment is established, a chosen set of animals of varying complexity will be introduced to the plant biome. There may be several different isolated biomes established within the surface base. The atmospheric constituents of the surface base will be maintained within defined limits by appropriate equipment. In the future the biomes will be harvested for food, wood and plant matter. The food may be used for eating, the wood may be used for building items and the plant matter may be processed for plastics, chemicals and fuels. The entire system may be tested on earth with reasonable accuracy. Heavy lift boosters and all of the other technology necessary for such an endeavor are currently available. Much heavier payloads may be placed on the moon than on any planet. The actual physical size of the first surface base is not important; but, it is vital for establishing remote processing, construction and plant/animal principles. As a more substantial base is desired, everything will be scaled up necessitating the need for heavy construction and processing equipment. This may be accomplished by launching one moderate size piece of equipment at a time. One large piece of equipment may be brought in over several launches and put together on the surface. Both construction and scientific work will take place in tandem. Several large vehicles loaded with scientific equipment will be capable of roving the entire surface. The large vehicles will be covered in solar cells in conjunction with large hydrogen and oxygen tanks that will power a fuel cell. It will be a closed system retaining all water, hydrogen and oxygen. The fuel cell will be backed up by batteries or supercapacitors. A small robotic vehicle may leave the larger vehicle to spread out a large sheet of solar cells to charge the hydrogen and oxygen tanks. Each large vehicle will have a small tilt rotor plane (if an atmosphere is present) that will be able to fly long distances carrying out scientific and scouting missions. It will eventually be practically and monetarily desirable to design a super heavy lift vehicle capable of moving very large payloads to planets. The fuel, engines, fuel pumps, turbines, . . . will be identical for all stages of the super heavy lift vehicle. More fuel and engines will be present in the lower stages. Every engine will be easily removable so that the entire rocket can be configured for each individual mission. The super heavy lift vehicle will be able to land upright on a planet under rocket control. The final stage will be designed so that the cargo bay touches the planet, a door may be opened and the equipment rolled onto the surface. This will require the fuel to be located above the cargo bay. The rockets will be located circumferentially around the base of the final stage with a nose cone covering everything. The diameter of all stages will be very substantial to permit the transport of large construction equipment. The super heavy lift vehicle will have a smaller height to diameter ratio than current boosters. The upper stages will be detachable and able to independently launch a super heavy payload to geosynchronous orbit. The final stage may be modified to permit a manned mission to a planet. It will be wise to design the super heavy lift vehicle to be multipurpose.

2.) Outer Space Base

A large surface base will provide for the establishment of a very substantial space base (i.e. gravity provided by rotation of the space base) when parts that are fabricated on the moon may be sent to the space base by a linear magnetic launcher. Until that time a unmanned space base of limited size may be quickly established, may provide for the testing of basic engineering principles, may obviate the need for life-support/protection considerations and may be low cost. This eventually will be transformed into a manned space base. The launch vehicle will carry all the required equipment and disassembled parts for a limited space base. Once the vehicle reaches the destination and is stabilized, the solar panels will be deployed. All power necessary for assembly and operation of the space base will be provided by the solar panels. Robots will construct the space base which will consist of components bolted together into the appropriate structure. The following is one of many variations that are possible for the robotic construction of the space base. Tubes will be joined together as discussed previously to form the basic framework of the space base. The remaining components will be attached to the framework to complete the space base. A strip running the length of each tube will have a linear gear track down the center with stabilizing tracks along either side. This will allow robots to move the length of the tube. Several motor driven gears of the robot will interface with the linear gear track. Extension elements on either side of the robot will connect to the stabilizing track of the strip. There may be several strips per tube. Special sections of tube will rotate the robots to the appropriate strip. The strips may be an integral part of the tube or the strips may be attached to the tube in space by sliding it into a specially machined groove and fixing it in place. Power to the robots may travel through the strips or long power cords. If the strips supply the energy, then the power lines (positive and ground) will couple from tube to tube via very slightly raised metal areas on the faceplates. These areas will be pressed together by the tension within the bolts. The robots may access the power through a sliding metal to metal contact between the robot's extension elements and the strip's stabilizing track. Each robot will have a reserve power pack. There may be multiple robots for faster construction or for backup in the event of a malfunction. The robots will have multiple attachments for all of the necessary functions needed in construction. The robots may communicate with the launch vehicle's main computers by a transceiver. Each robot will have a digital camera for autonomous real time control, for external monitoring of progress and for remote control of construction. Hence, construction can be completed autonomously or controlled remotely form earth. New capabilities or corrections may be reprogrammed while in orbit. All construction materials will be composed of a strong, rigid, lightweight material. It may be necessary to divide the tubes lengthwise to allow for efficient stacking to minimize storage volume on the launch vehicle. Periodic tabs along the length of each edge may be bolted together to form the tube. The faceplates may be attached in space. All of the technology necessary for such an endeavor is readily available. A significant portion of the space base construction may be tested on the ground.

1.) Specially designed objects (i.e. bolts, materials to be joined together, power sources) that may be required for building structures in space (surface based construction—moon/planet/asteroid and space based construction—outer space).

2.) Referring to claim 1, any variation of a bolt may be modified as follows:
add to the threaded end of the bolt an unthreaded cylindrical section followed by an unthreaded tapered/conical section;
the diameter of the cylindrical section is slightly less than the inside diameter of the nut;
the diameter of the cylindrical and conical/tapered sections are equal at their junction;
the junctional end of the conical section has the largest conical diameter;
appropriate contouring of the edges;
any quantity of material may be removed from the cylindrical and tapered/conical sections such that the remaining material is sufficient to guide the nut;
all dimensions are appropriate for the particular application.

3.) Referring to claim 1, the construction material may be modified to have male/female interfaces that may be used for the alignment of parts (i.e. alignment of attachment sites (bolt holes) by aligning the male/female interface, the correct placement of a piece of material relative to other pieces of material by aligning the male/female interface).

4.) Referring to claim 1, the construction material may be designed so that additions may be continuously added to an existing structure.

5.) Referring to claim 1, all the construction/power material may be prefabricated and sent to the desired destination for human/robotic construction.

6.) Referring to claim 1, specially designed objects (i.e. bolts, materials to be joined together, power sources) may provide for efficient human/robotic construction.

7.) Referring to claim 1, a power system may be established by:
selecting long performing efficient solar cells;
thinning the backplane of the solar cell to an appropriate thickness (i.e. less than 1 mm);
producing on the thinned solar cell an appropriate electrical pattern;
producing a thin flexible sheet with an appropriate electrical pattern;
attaching many of the thinned solar cells to the thin flexible sheet through the appropriate combination of surface preparation, heat, pressure and chemicals;
establishing an appropriate connection between the flexible sheet and the end user (i.e. power conversion, beam energy from solar cells to surface via electromagnetics).
